(19) United States
(12) Patent Application Publication
(10) Pub. No.: US 2011/0205752 A1
(43) Pub. Date: Aug. 25, 2011

(54) Lighting Device

(76) Inventors: Derek J. Allen, Silver Spring, MD (US); Dominic DeSantis, Silver Spring, MD (US)

(21) Appl. No.: 12/711,977

(22) Filed: Feb. 24, 2010

(51) Int. Cl. H01L 33/00; F21S 4/00; F21V 1/00; F21L 4/02

(52) U.S. Cl. 362/555; 362/249.02; 362/235; 362/184

(57) ABSTRACT

A lighting device is described. In accordance with one implementation, a lighting device comprises a housing having a top wall operably connected to a bottom wall. The housing has a front and a rear, and a cover is operably connected to the rear of the housing. At least one mechanism is located on at least one of the walls of the housing for operably connecting the lighting device to a second lighting device. A mechanism for holding at least one light-emitting diode is operably connected to the front of the housing and a power source. At least one light-emitting diode is installed on the mechanism for holding the at least one light-emitting diode.

### TECHNICAL FIELD

This application relates in general to lighting devices.

### BACKGROUND

When photographs are taken in a studio, lighting devices typically are used. Likewise, lighting devices generally are used when filming movies or videos. The lighting devices usually are heavy and become hot with continued use. The heat generated may be from the type of light bulb used in the lighting device. In addition, traditional lighting devices generally use a significant amount of electrical power.

### SUMMARY

This application describes a lighting device.

In accordance with one implementation, a lighting device comprises a housing having a top wall operably connected to a bottom wall. The housing has a front and a rear, and a cover is operably connected to the rear of the housing. At least one mechanism is located on at least one of the walls of the housing for operably connecting the lighting device to a second lighting device. A mechanism for holding at least one light-emitting diode is operably connected to the front of the housing and a power source. At least one light-emitting diode is installed on the mechanism for holding the at least one light-emitting diode.

In accordance with another implementation, a lighting device comprises a housing having a top wall operably connected to a bottom wall via side walls. The housing has a front and a rear, and a cover is operably connected to the rear of the housing. A first mechanism for operably connecting the lighting device to a second lighting device is located on at least one of the side walls of the housing. A second mechanism for operably connecting the lighting device to the second lighting device is located on at least one of the top wall and bottom wall of the housing. A mechanism for holding a plurality of light-emitting diodes is operably connected to the front of the housing and a power source. A plurality of LEDs is installed on the mechanism for holding the plurality of light-emitting diodes.

The details of one or more implementations are set forth in the accompanying drawings and the description below. Other features, aspects, and advantages will become apparent from the description, the drawings, and the claims. It is to be understood that the foregoing general description and the detailed description are exemplary, but not restrictive of the lighting device or the method for making the lighting device.

### DESCRIPTION OF DRAWINGS

In the drawings, which are discussed below, one or more implementations are illustrated. It is understood that the lighting device is not limited to the implementations depicted in the drawings herein, but rather it is defined by the claims appended hereto and equivalent structures.

FIG. 1 is a front perspective view of an exemplary implementation of the lighting device.

FIG. 2 is a front perspective view of an exemplary implementation of the lighting device without a snoot.

FIG. 3 is a rear perspective view of the lighting device of FIG. 2.

FIG. 4 is a front view of the lighting device of FIG. 2.

FIG. 5 is a top view of the lighting device of FIG. 2.

FIG. 6 is a bottom view of the lighting device of FIG. 2.

FIG. 7 is a partial view of the lighting device of FIG. 2.

FIG. 8 is a partial view of the lighting device of FIG. 2.

FIG. 9 is a rear view of the lighting device of FIG. 2.

FIGS. 10A-10D is an exemplary implementation of an assembly chassis that may be used in the lighting device of FIG. 2.

FIGS. 11A-11L is an exemplary implementation of a chassis that may be used in the lighting device of FIG. 2.

FIGS. 12A-12F is an exemplary implementation of a rear cover assembly that may be used in the lighting device of FIG. 2.

FIGS. 13A-13J is an exemplary implementation of a cover that may be used in the lighting device of FIG. 2.

FIGS. 14A-14D is an exemplary implementation of a battery door assembly that may be used in the lighting device of FIG. 2.

FIGS. 15A-15D is an exemplary implementation of a battery door that may be used in the lighting device of FIG. 2.

FIGS. 16A-16D is an exemplary implementation of a snoot with a grid that may be used in the lighting device of FIG. 2.

FIGS. 17A-17C is an exemplary implementation of a lens cover that may be used in the lighting device of FIG. 2.

FIGS. 18A-18B is an exemplary implementation of a series of lighting devices of FIG. 2 with a latch that may be used to secure the lighting devices to each other.

FIGS. 19A-19E is an exemplary implementation of an adapter that may be used in the lighting device of FIG. 2.

FIG. 20 is an exemplary implementation of a series of lighting devices of FIG. 1 operably connected to each other.

FIG. 21 is an exemplary implementation of a series of lighting devices of FIG. 1 operably connected to each other.

FIGS. 22A-22B show an exemplary implementation of the lighting device of FIG. 2 on a tripod.

Like reference symbols in the various drawings indicate like elements.

### DETAILED DESCRIPTION

While the specification concludes with claims particularly pointing out and distinctly claiming subject matter, the lighting device will now be further described by reference to the following detailed description of exemplary implementations taken in conjunction with the above-described accompanying drawings. The following description is presented to enable any person skilled in the art to make and use the lighting device. Descriptions of specific implementations and applications are provided only as non-limiting examples and various modifications will be readily apparent to those skilled in the art. The general principles defined herein may be applied to other implementations and applications without departing from the spirit and scope of the lighting device. Thus, the lighting device is to be accorded the widest scope encompassing numerous alternatives, modifications, and equivalents consistent with the principles and features disclosed herein. For purpose of clarity, details relating to technical material that is known in the technical fields related to the lighting device have not been described in detail so as not to unnecessarily obscure the present application.

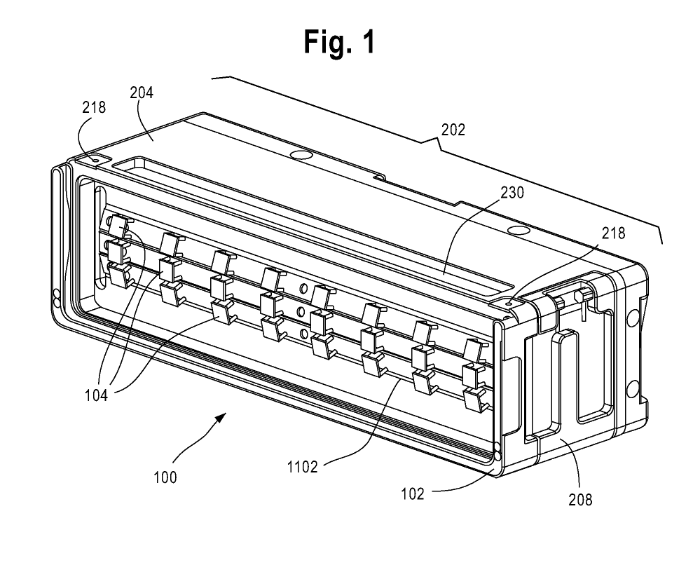

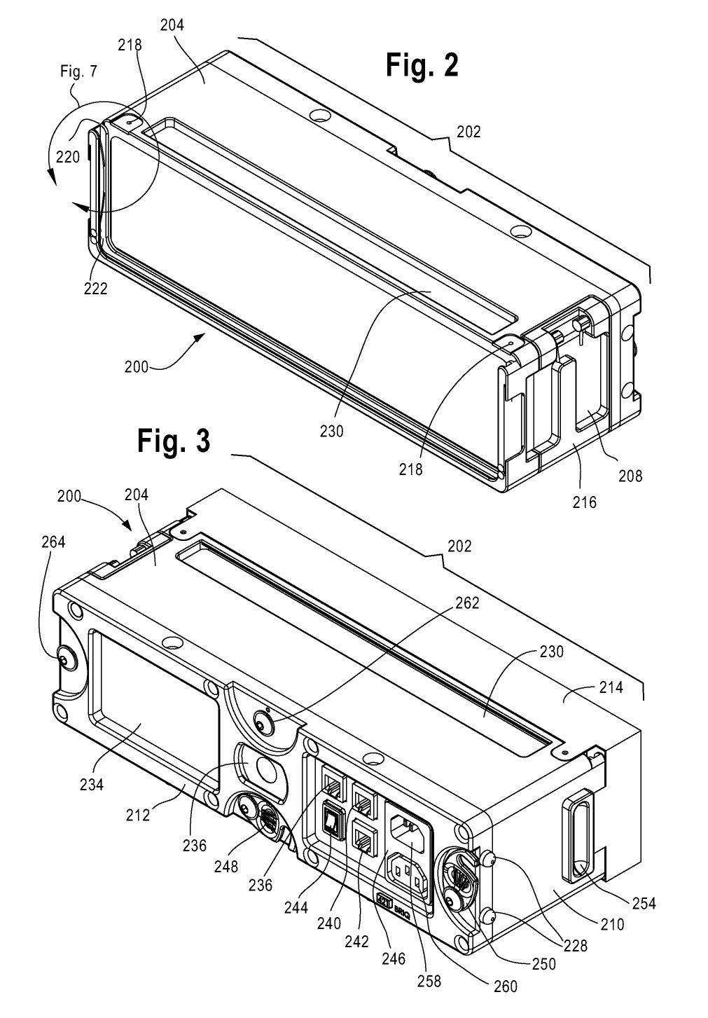

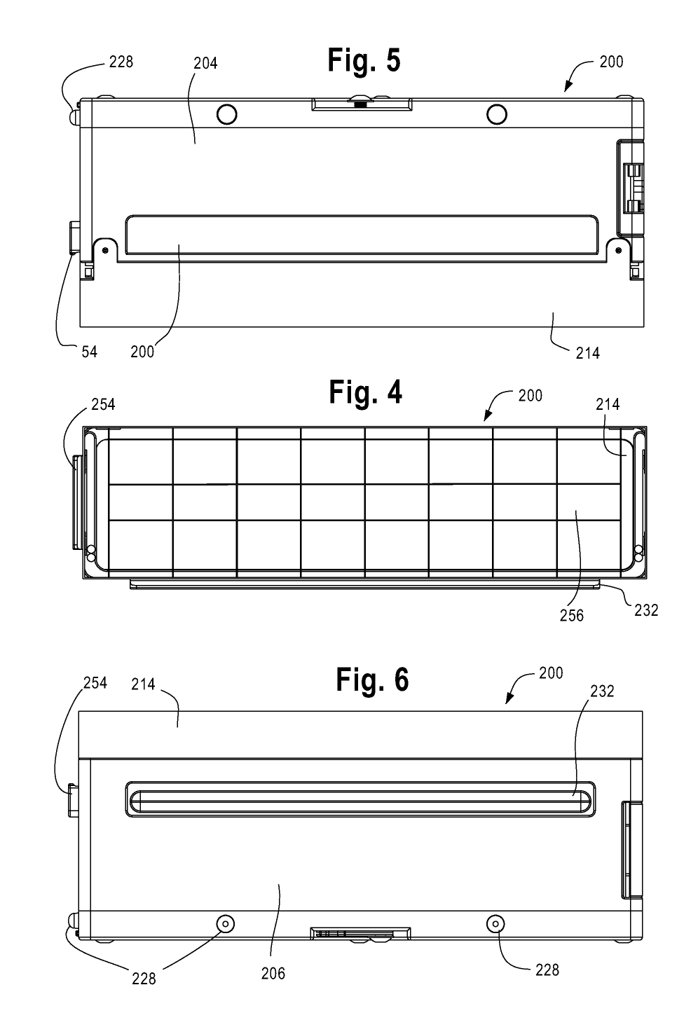

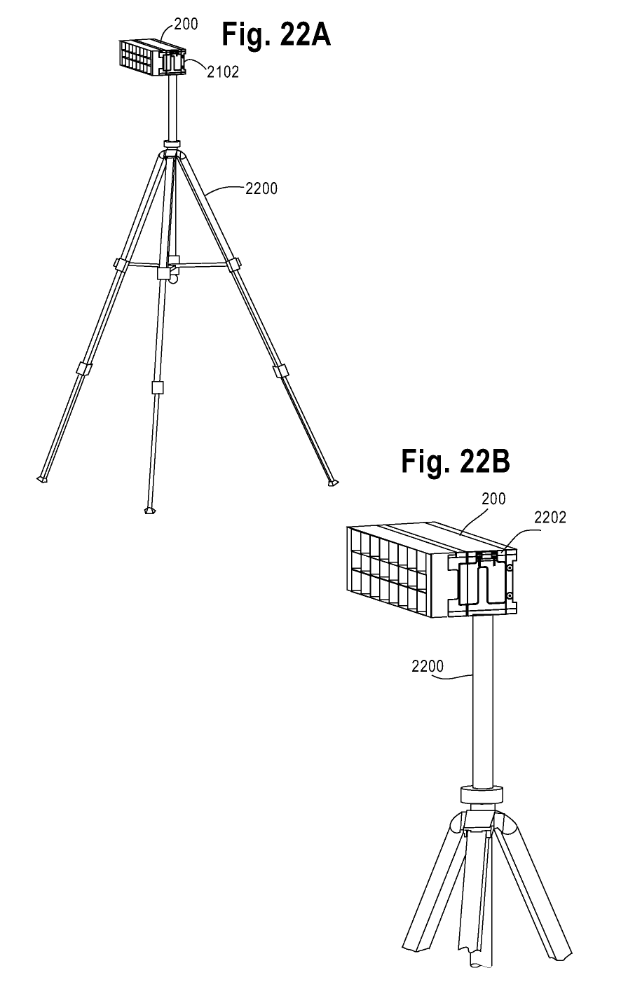

FIG. 1 shows a lighting device 100 with a plurality of light-emitting diodes (LEDs) 104 operably connected to a mechanism 1102 for holding the plurality of LEDs, and the lighting device 100 has a snoot 102 operably connected to the front of the housing 202. FIGS. 2-33 show a lighting device 200 without a snoot. FIG. 4 shows the lighting device of FIGS. 2-3 with a snoot 214 and a grid 256. The arrangements of the snoots 102, 214, the grid 256, and the LEDs 104 are not limited to the arrangements shown in the figures.

The lighting device 200 has a housing 202. As shown, the housing 200 has a top wall 204 and a bottom wall 206. The top and bottom walls 204, 206 may be directly or indirectly connected to each other. In the figures, the top and bottom walls 204, 206 are connected to each other through side walls 208, 210. In some implementations, the top and bottom walls 204, 206 may be connected to each other without sidewalls 208, 210. In some implementations, the top and bottom walls 204, 206 may be connected to each other through at least one side wall. In some implementations, the top and bottom walls 204, 206 may be connected to each other through more than two side walls.

In some implementations, the top and bottom walls 204, 206 may have widths of about 12 inches to about 12.5 inches and lengths of about 3 inches to about 5 inches. In some implementations, the sidewalls 208, 210 may have lengths of about 3 inches to about 4 inches and widths of about 3 inches to 4 inches. In some implementations, the top and bottom walls 204, 206 may have widths of about 12.2 inches and lengths of about 4.9 inches. In some implementations, the top and bottom walls 204, 206 may have widths of about 12.0 inches and lengths of about 3.3 inches. The dimensions set forth in this paragraph are not to be deemed limiting of the dimensions of the lighting device 200 and various dimensions may be used for the lighting device described herein.

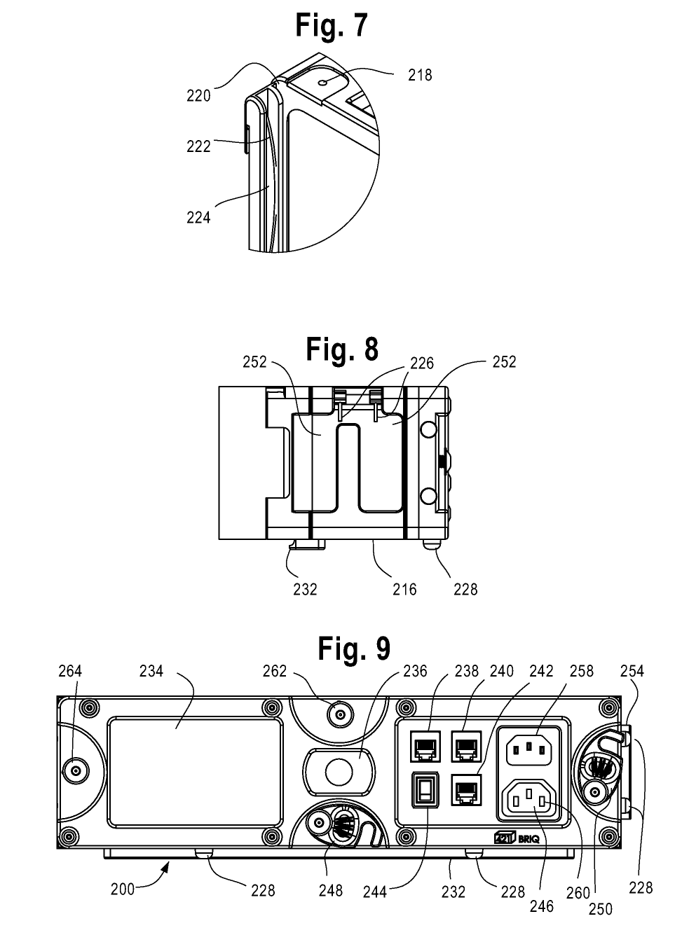

In some implementations, the lighting device 200 has a cover 212 connected to the rear of the housing 202 and, as shown in FIG. 4, a snoot 214 may be connected to the front of the housing 202. Referring to the area designated by B in FIG. 2 and as shown in FIG. 7, the lighting device 200 may have a snoot detainer 218 located on the top wall 204 for connecting the snoot 214 to the front of the housing 202. In some implementations, the snoot detainer 218 may be located on the bottom wall 206. In some implementations, the snoot detainer 218 may be located on both the top and bottom walls 204, 206. In some implementations, the snoot detainer 218 may be located on at least one side wall 208, 210. In some implementations, a diffuser slot 220 may be located on the front of the housing 202. In some implementations, a gel slot 222 may be located on the front of the housing 202. In some implementations, an optional retainer mechanism 224 may be present for retaining the gel inserted into the gel slot 222. As shown, the retainer mechanism 224 is a clip. In some implementations, the retainer mechanism 224 may be a tab, a clamp, a ring, a tongue or groove, tape, a frame, a holder, or any mechanism suitable for securing the gel into the gel slot.

An optional grid 256 may be operably connected to the front of the housing 202. When the optional grid 256 is present, the grid 256 may alter the light being generated by the lighting device 200.

An optional battery door assembly 216 is located on at least one wall of the housing 202. As shown in FIG. 2, the battery door assembly 216 is located on the side wall 208. In some implementations, the battery door assembly 216 is incorporated into the side wall 208. As a non-limiting example, the battery door assembly 216 may form the side wall 208 by itself and if the battery door assembly 216 were removed, the housing 202 may have a void where the battery door assembly 216 was located. In some implementations having a battery door assembly 216, a battery door latch release 226 may be present to permit opening of the battery door. As shown, moving the battery door release 226 towards the middle of the battery door assembly 216 permits the battery door to be opened.

In some implementations of the lighting device 200, a mechanism for connecting the lighting device 200 to at least one other lighting device 200 or other object may be present. As shown, the lighting device 200 may include an interconnect, such as, but without limitation, a groove 252 and a tongue 254 configured so that a second lighting device 200 may be operably connected the lighting device 200 via the corresponding groove 252 or tongue 254. In some implementations, the lighting device 200 includes a groove 252 configured to receive a tongue 254 from a second lighting device 200. In some implementations, the lighting device 200 includes a tongue 254 to be inserted into a groove 252 of a second lighting device 200.

As shown, the groove 252 is located on the side wall 208 of the housing 202 and the tongue is located on opposite side wall 210 of the housing 202. In some implementations, the lighting device 200 includes a tongue 232 and a groove 230 for receiving the tongue 232 from a second lighting device 200. As shown, the tongue 232 is located on the top wall 202 of the housing 202 and the groove 230 is located on the bottom wall 206 of the housing 202.

In some implementations, an optional latch 248, 250 may be present to secure a lighting device 200 to another lighting device 200 or other object. In some implementations, latch 248 may be present to secure the mechanism 262 for connecting the lighting device 200 to another lighting device 200 or other object containing the mechanism 262 suitably positioned to make contact with the latch 248. In some implementations, latch 250 may be used to secure the mechanism 264 for connecting the lighting device 200 to another lighting device 200 or other object containing the mechanism 264 suitably positioned to make contact with the latch 250. In some implementations, latch 248 and latch 250 may be present. In some implementations, if latch 248 or latch 250 is present, the latch is located at a position for receiving the corresponding connecting mechanism 262, 264. In some implementations, the corresponding connecting mechanism 262, 264 is an interconnect. In some implementations, the latch 248, 250 may be located on the rear cover 212.

In some implementations, the mechanism for connecting the lighting device 200 to at least one other lighting device 200 may be a nut, a bolt, a dowel, a lug, a pin, a rivet, a screw, a hook-and-loop fastener, a snap-lock mechanism, a press-fit mechanism, a bracket-type mechanism, a slide-and-lock mechanism, a twist-and-lock or other friction-fit mechanism, a tongue-and-groove mechanism, a buckle mechanism, a joint, or any other suitable mechanism for securing one lighting device 200 to a second lighting device 200.

In some implementations, at least one stabilizer 228 is located on the housing 202. The stabilizer 228 may help balance a lighting device 200 that is connected to another lighting device 200. The stabilizer 228 may balance a lighting device 200 that is set on a surface.

The battery door assembly 216 may include at least one groove 252 for receiving the tongue 254 located on a second lighting device 200. In some implementations that do not have a battery door 216, at least one side of the housing 202 has a groove 252 for receiving a tongue 252 located on a second lighting device 200.

In some implementations, the rear cover 212 of the housing 202 may have a control panel 234. The control panel 234 may be an LCD control panel, at least one knob, at least one switch, a display with at least one knob, soft touch switches, combinations of the foregoing, or any suitable mechanism for controlling the lighting device 200.

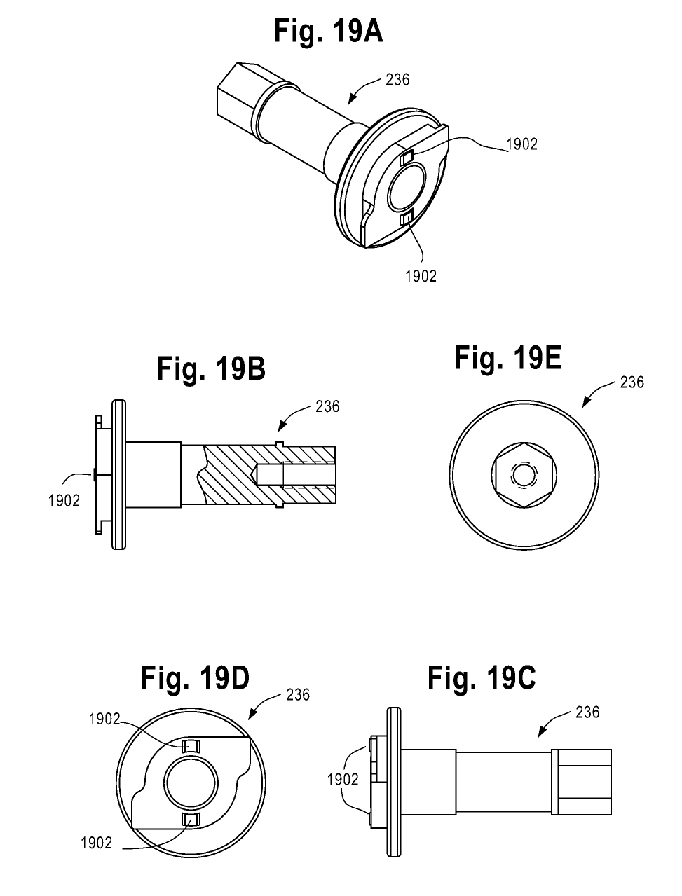

In some implementations, the rear cover 212 may have a connector 236 for mounting the lighting device 200 on a stand. An implementation of the connector 236 is shown in FIG. 19. In some implementations, the connector 236 is made of aluminum. In some implementations, the connector 236 is made of plastic, metal, including, but not limited to steel, or any other material suitable for mounting the lighting device 200 on a stand. A non-limiting example of a lighting device 200 mounted on stand is shown in FIG. 21. The stand 2200 has an end 2202 that is received by the connector 236 of the lighting device 200. The connector 236 may be a universal connector capable of receiving more than one type of stand. In some implementations, the connector 236 is located on at least one of the walls 204, 206, 208, 210 of the housing 202.

In some implementations, the rear cover 212 may have at least one data port 238 operably connected to a processor located within the lighting device 200. In some implementations, the data port 238 may be used to update firmware for the lighting device 200. In some implementations, the data port 238 may be used to control the lighting device 200 with control signals. In some implementations, the lighting device 200 may have a dimmer. The dimmer may be controlled by DMX in/out ports 240, 242 located on the rear cover 212. The dimmer may be operably connected to the lights of the lighting device 200. In some implementations, a power switch 244 may be located on the rear cover 212. In some implementations, the power switch 244 is located on one of the walls of the housing 202 of the lighting device 200. The power switch 244 may be operably connected to the lights of the lighting device 200. In some implementations, the lighting device 200 is powered through A/C current and the mechanism for A/C power in and distribution 246 may be located on the rear cover 212. When the lighting device 200 is powered through A/C current, the mechanism 246 is operably connected to the lights in the lighting device 200. In some implementations a power source provides about 11 to about 14 volts of electrical current to power the lighting device 200.

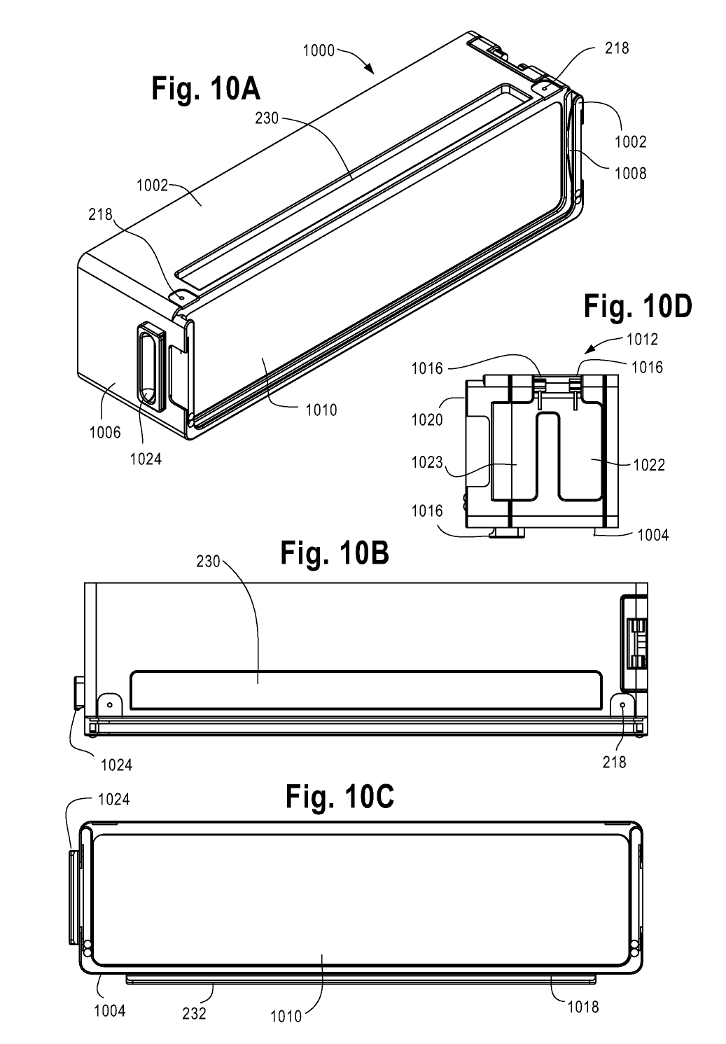

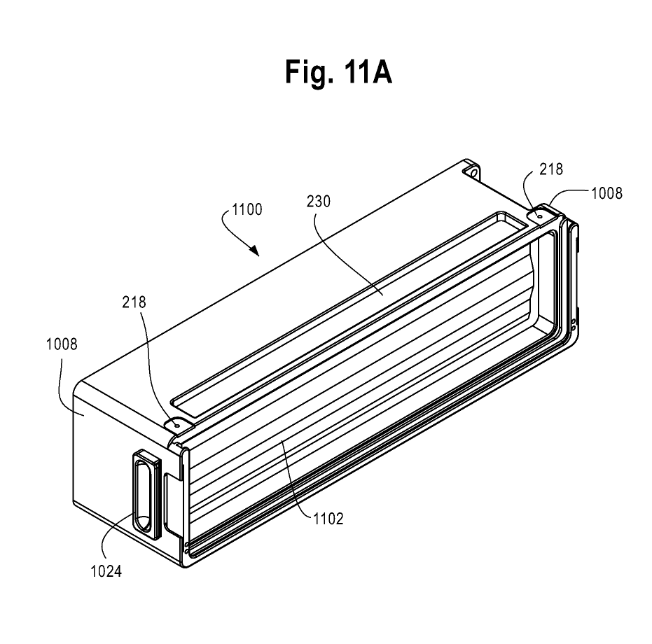

FIG. 10 shows an assembly chassis 1000 that may be used to create the lighting device 200 of FIG. 2. The assembly chassis 1000 has a top wall 1002 and a bottom wall 1004 connected to each other via side walls 1006, 1008. The front of the assembly chassis has an opening 1010. In some implementations, the assembly chassis 1000 has a width of about 12 inches and a length of about 3.25 inches. In some implementations, the opening 1010 in the front of the assembly chassis is configured to receive or be operably connected to a lens cover 910. In some implementations, the opening 1010 is sized and configured to receive or be operably connected to a lens cover 910 having a width of about 11.42 inches and a length about 2.76 inches.

In some implementations, a battery door assembly 1012 is located on at least one side of the assembly chassis 1000. As shown in FIG. 10D, the battery door assembly 1012 is located on side wall 908. In some implementations, the battery door assembly 1012 also is the side wall 908 (e.g., removing the battery door assembly 1012 from the assembly chassis 1000 may create a void in the assembly chassis 1000). The battery door assembly 1012 is made of a battery door 1014 that is attached to the side wall 1008 via a latch release 1016. In some implementations, the battery door assembly 1012 has a length of about 3.250 inches and a width of about 2.020 inches to about 3.250 inches. In some implementations, the battery door assembly may have at least one groove 1022 for receiving a tongue 1024 located on a lighting device. As shown, the tongue 1024 is about 2.000 inches long and about 0.708 inches wide. The at least one groove 1022 is sized and shaped to receive the tongue 1024 of another lighting device. It is understood by one skilled in the art that the shape and measurements for the battery door assembly 1012 may be any that are suitable for the purposes described herein and may vary from those specified in this paragraph and shown in the figures.

A mechanism 1018 for connecting the assembly chassis 1000 to a second assembly chassis may be located on the bottom wall 1004 of the assembly chassis 1000. As shown, the mechanism 1018 is a tongue having a width of about 10 inches and a length of about 0.750 inches. The back end of the vertical interconnect lock 1018 may be located about 1.250 inches from the approximate edge 1020 of the side wall 1008. A corresponding groove 230 may be located on the opposite wall of the assembly chassis 1000.

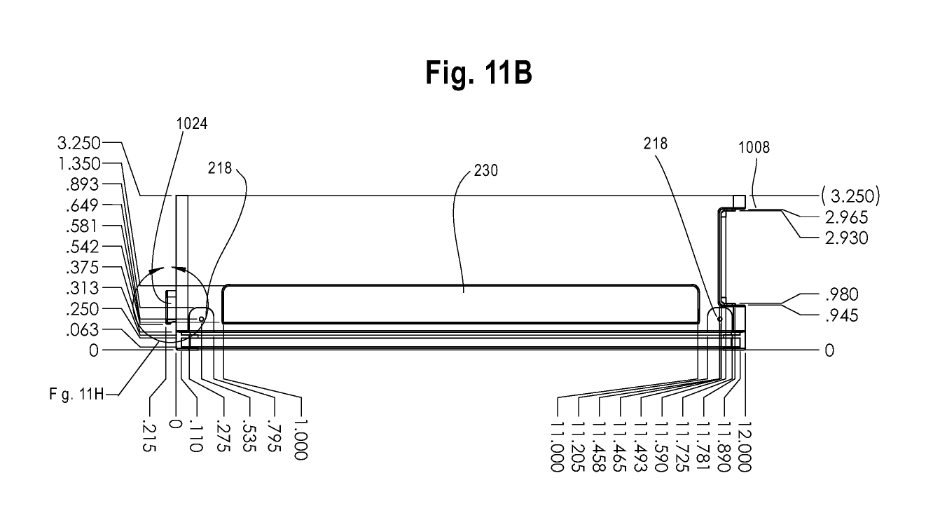

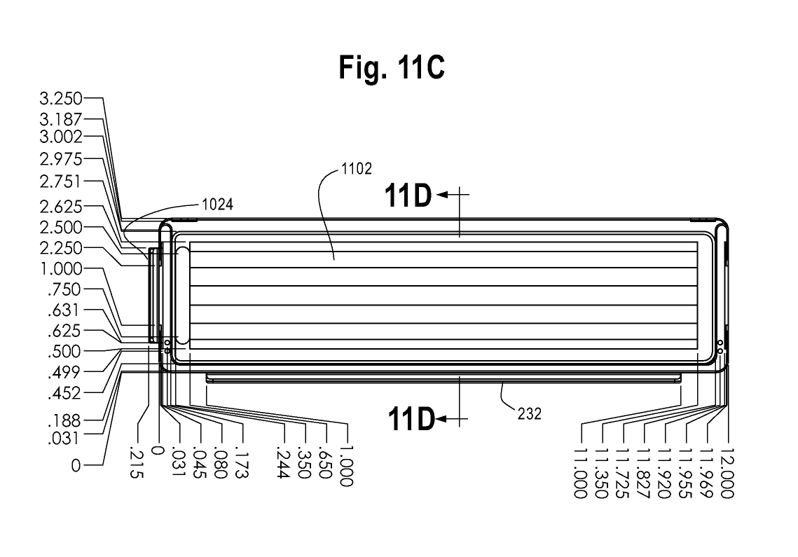

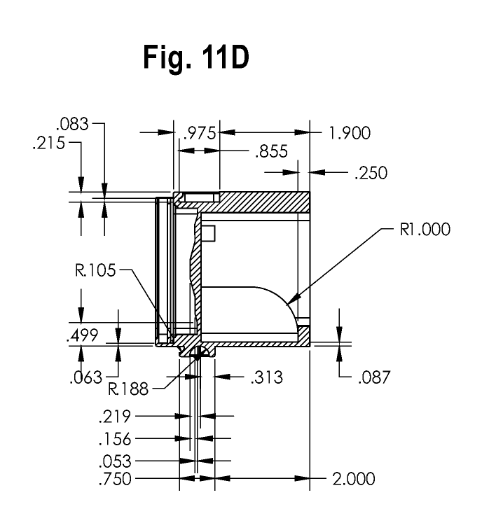

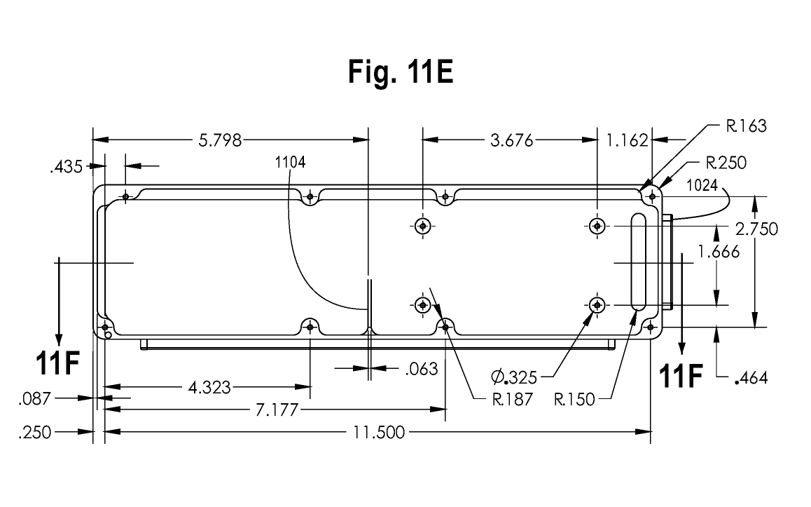

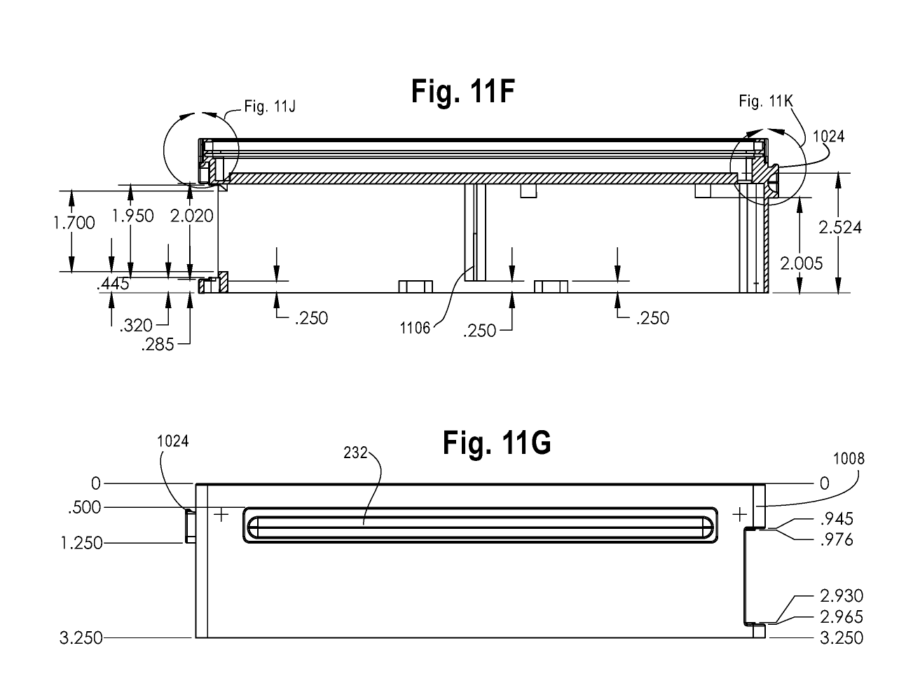

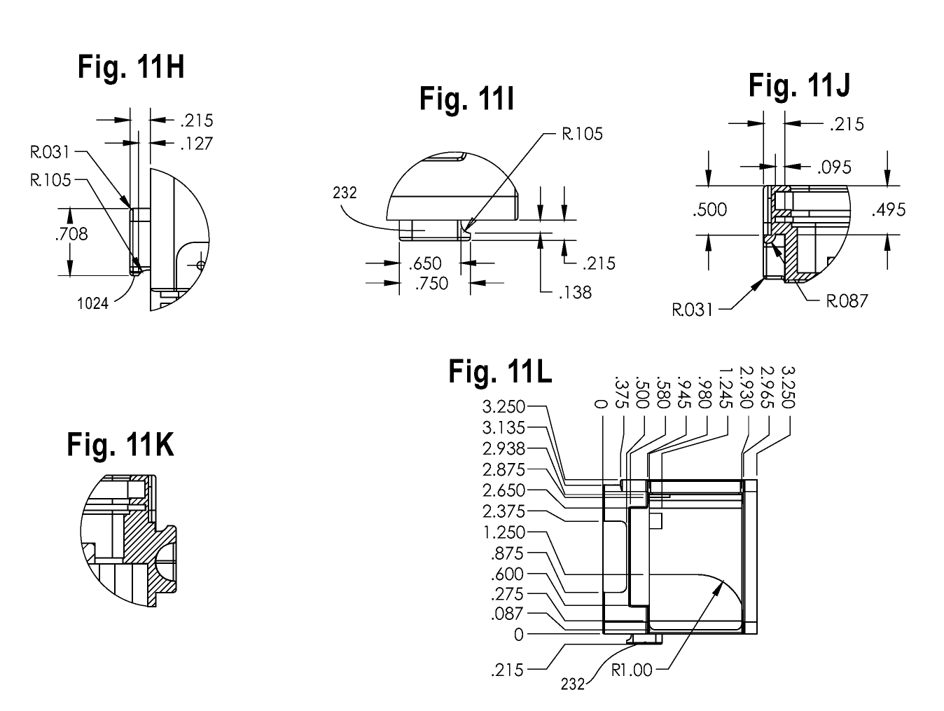

FIG. 11 shows an implementation of a chassis 1100 that may be used for the lighting device. The chassis 1100 is the same as the assembly chassis 1000, but as shown, the chassis 1100 has a mechanism 1102 for holding at least one LED and it does not have the battery door assembly 1012 installed. In some implementations, the mechanism 1102 for holding at least one LED may be connected to the front of the chassis 1100. In some implementations, the mechanism 1102 for holding at least one LED may be connected to a snoot.

LEDs may be installed on the mechanism 1102 so that the LEDs form an array of LEDs. In some implementations, the mechanism 1102 may be operably connected to or incorporate a control circuit or a light circuit. In some implementations, the light circuit may include the LEDs and the conductors between them. In some implementations, the conductors may be parallel paths of series wiring of the rows of LEDs.

In some implementations, a control circuit may be operably connected to the power source and LEDs. As stated above, in some implementations, the control circuit may be operably connected to or incorporated into the mechanism 1102. The control circuit may maintain a constant current through the electrical paths used to power the LEDs. In some implementations, the control circuit uses Pulse Width Modulation (PWM) technology to effect the time on of the input voltage to change the LED output (e.g., PWM technology permits dimming the LEDs). In some implementations, autotransformers are used for dimming the LEDs. In some implementations, the effective dimming range may be between about 10% to about 95% of full power. In some implementations, the effective dimming range may be between about 15% to about 95% of full power. In some implementations, the effective dimming range may be between about 20% to about 95% of full power. In some implementations, the effective dimming range may be from about 0% to about 99% of full power. In some implementations using a dimming range below about 10%, although the dimming may be controlled to about 0% of full power, an appearance of “flickering” or some other visible effect of the low power may be seen by a viewer of the lighting device.

In some implementations, a potentiometer (not shown) may be operably connected to the control circuit and the potentiometer may control the PWM signal.

In some implementations, the mechanism 1102 for holding LEDs is a plurality of horizontal rows. In some implementations, the angle of each horizontal row differs from the angle of its adjacent horizontal row. This may result in the LEDs being pitched. In some implementations, not all of the LEDs may point in the same direction due to the angle of the horizontal rows. In some implementations, all or substantially all of the LEDs may point in the same direction. In some implementations, as shown in FIG. 1, three horizontal rows of LEDs are present and the center horizontal row of LEDs is positioned so that the center of the beam of light emitted from the LEDs is perpendicular or approximately perpendicular to the face of the lighting device 100; the upper horizontal row of LEDs is positioned so that the center of the beam of light emitted from this row of LEDs is about 15° above the perpendicular to the face of the lighting device 100; and the lower horizontal row of LEDs is positioned so that the center of the beam of light emitted from this row of LEDs is about 15° below the perpendicular to the face of the lighting device 100.

In some implementations, as shown in FIG. 1, three horizontal rows of LEDs are present and the center horizontal row of LEDs is positioned so that the center of the beam of light emitted from the LEDs is perpendicular or approximately perpendicular to the face of the lighting device 100; the upper horizontal row of LEDs is positioned so that the center of the beam of light emitted from this row of LEDs is about 10° to about 25° above the perpendicular to the face of the lighting device 100; and the lower horizontal row of LEDs is positioned so that the center of the beam of light emitted from this row of LEDs is about 10° to about 25° below the perpendicular to the face of the lighting device 100.

In some implementations, as shown in FIG. 1, three horizontal rows of LEDs are present and the center horizontal row of LEDs is positioned so that the center of the beam of light emitted from the LEDs is perpendicular or approximately perpendicular to the face of the lighting device 100; the upper horizontal row of LEDs is positioned so that the center of the beam of light emitted from this row of LEDs is about 5° to about 30° above the perpendicular to the face of the lighting device 100; and the lower horizontal row of LEDs is positioned so that the center of the beam of light emitted from this row of LEDs is about 5° to about 30° below the perpendicular to the face of the lighting device 100.

In some implementations, a user may be able to change the angle of one or more rows of the lighting device either manually or electronically. In some implementations, the horizontal rows are parallel to each other. In some implementations, the mechanism 1102 for holding the LEDs is one horizontal row.

The mechanism 1102 for holding the LEDs may be operably connected to a power source so that when the lighting device is powered on and LEDs are mounted on the mechanism 1102, the LEDs are capable of being lit. The mechanism 1102 for holding at least one LED may be operably connected to a power source. The power source may be a battery, solar panels, AC current originating from outside of the lighting device, or other sources of power that may be used to provide electricity to at least one LED.

In some implementations the LEDs are wired in series. In some implementations, three horizontal parallel rows of LEDs are installed on mechanism 1102. In some implementations having three horizontal parallel rows, eight LEDs are mounted on each row and eight electrical paths may be used to control the LEDs. In some implementations having three horizontal parallel rows, 10 LEDs may be mounted on each horizontal row and ten electrical paths may be used to control the LEDs. In some implementations having more or less than three horizontal rows, eight LEDs may be mounted on each horizontal row and eight electrical paths may be used to control the LEDs. In some implementations having more or less than three horizontal rows, 10 LEDs may be mounted on each horizontal row and ten electrical paths may be used to control the LEDs.

FIG. 11 shows exemplary approximate measurements in inches for the chassis 1100. One skilled in the art recognizes that the chassis 1100 may be created using measurements that are different from the measurements specified in the figure, and the measurements specified in the figure do not limit the design of the chassis.

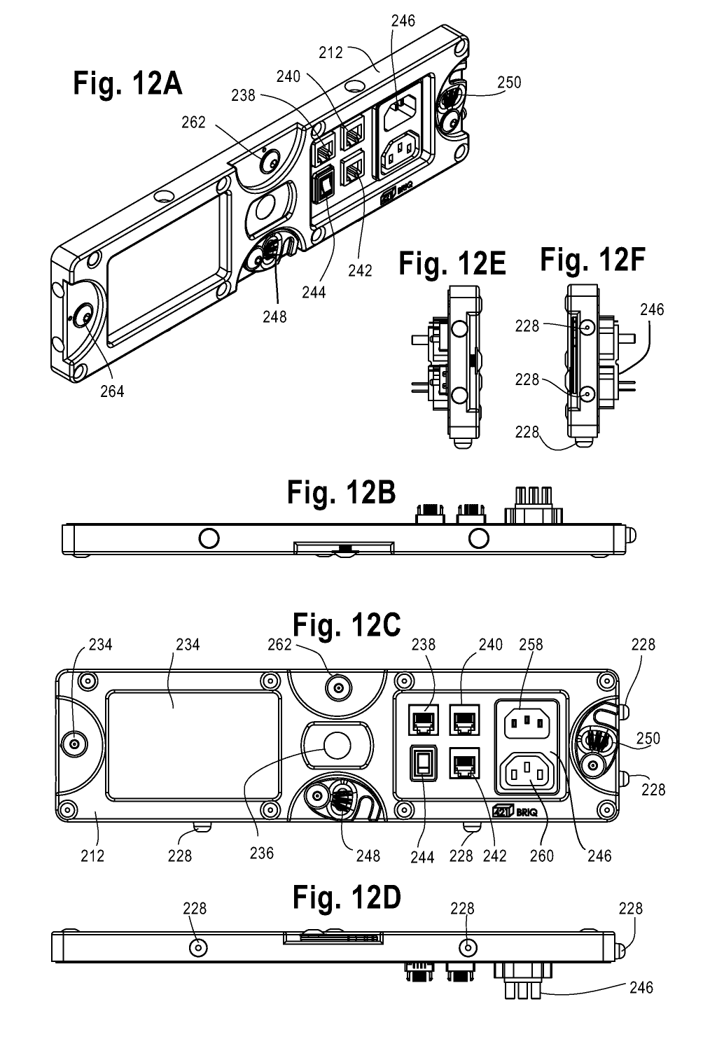

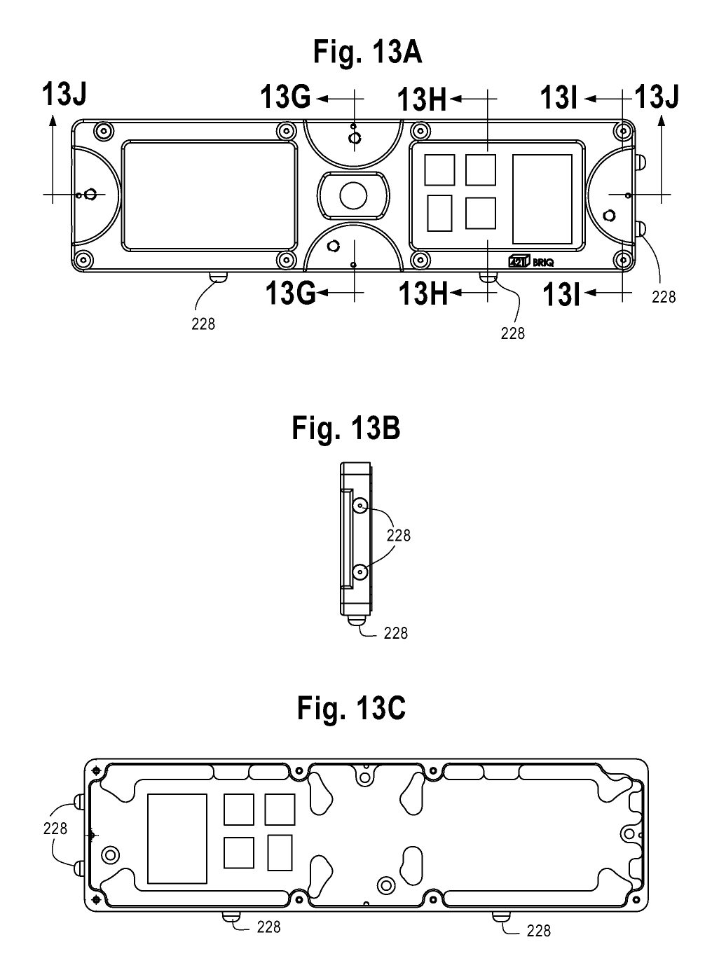

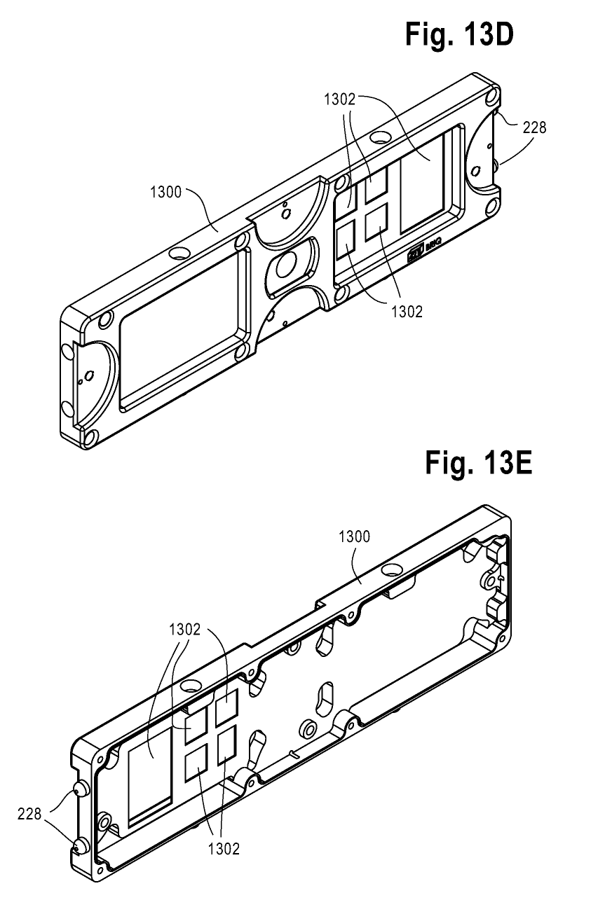

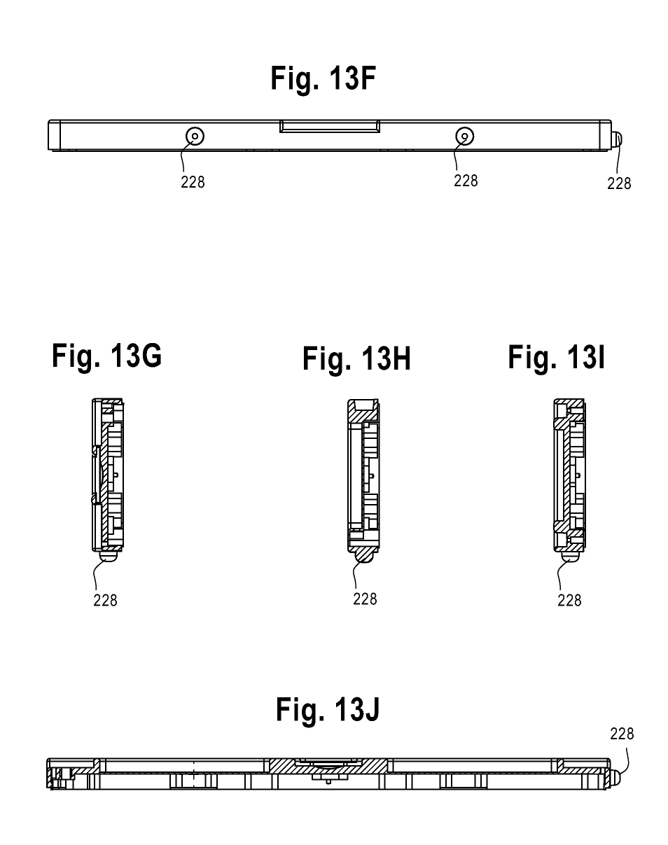

FIG. 12 shows the rear cover 212. In some implementations, the rear cover 212 has a width of about 12.000 inches to about 12.215 inches and a length of about 0.625 inches to about 0.714 inches. The rear cover 212 includes a panel 1300, shown in FIG. 13. The panel 1300 may have holes or voids 1302 sized and configured so that the panel 1300 may provide access to the data port 238, dimmer 240, 242, power switch 244, and the mechanism for A/C power in and distribution 246. If a control panel is located on the rear cover 212, then the panel 1300 may include holes or voids to receive wires, knobs, switches, or components thereof.

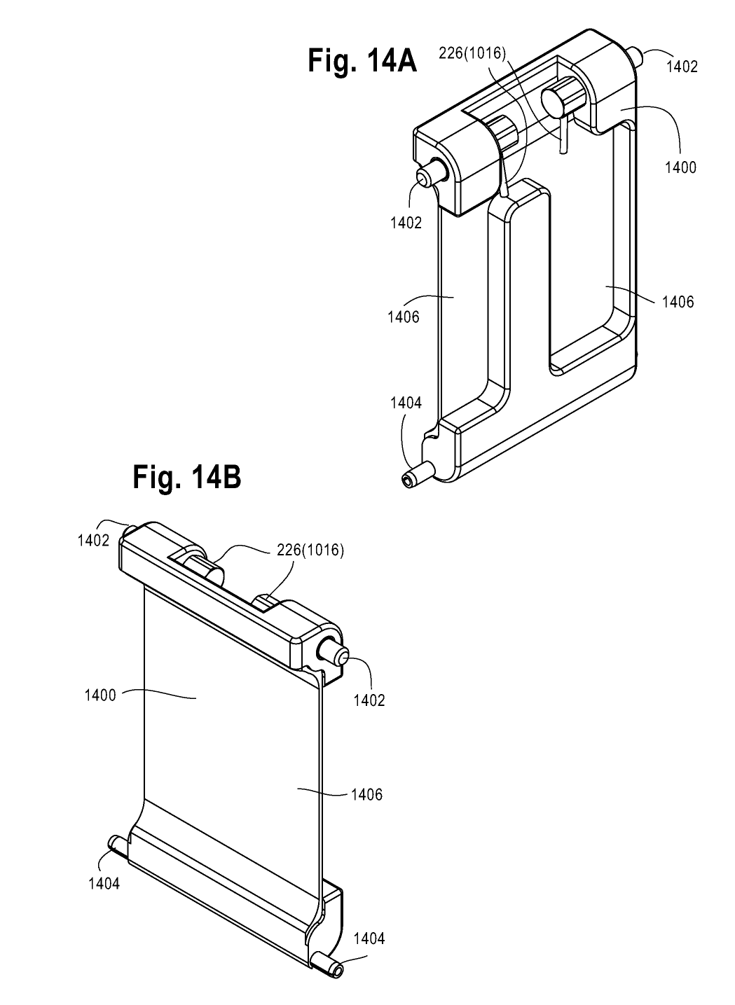

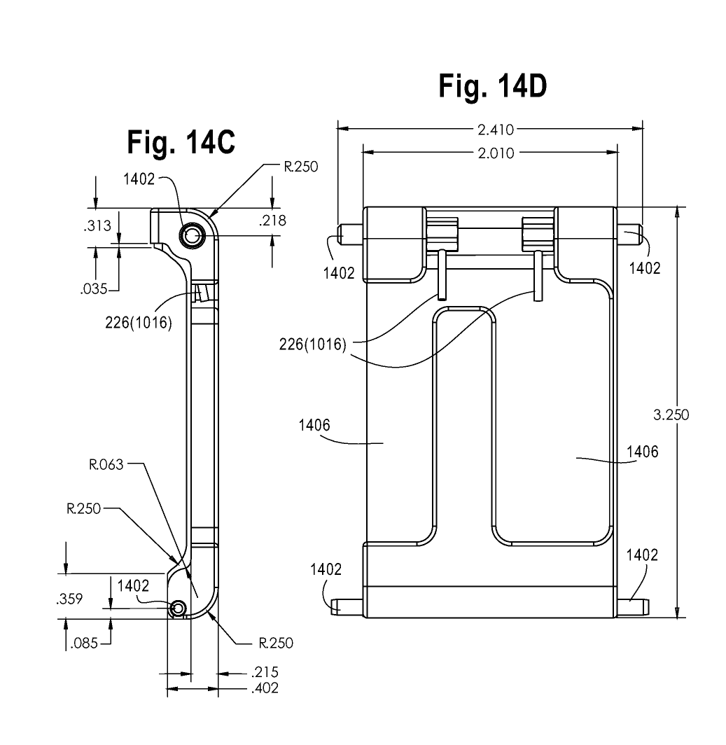

An implementation of a battery door assembly is shown FIG. 14. The battery door assembly may have a door 1400 that has at least one pin 1402 operably connected to the door 1400. As shown, two pins 1402 are present. In some implementations, only one pin 1402 is present. In some implementations, the at least one pin 1402 may be part of the battery door latch release 226, 1016.

At least one plunger or spring 1404 may be operably connected to the door 1400. In some implementations, at least one groove 1406 is present on the door 1400 to receive a tongue located on a lighting device or other object. When a groove 1406 is present on one side of the door 1400, the groove may not extend all the way through the door, as shown in FIGS. 14A and 14B, and the rear of the door 1408 may be flat or substantially flat.

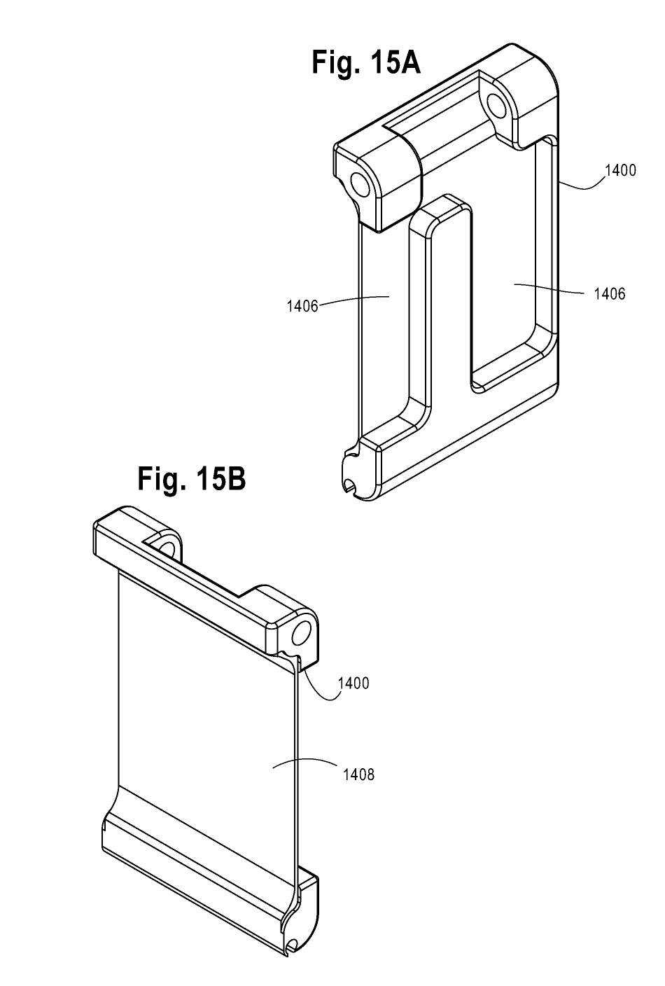

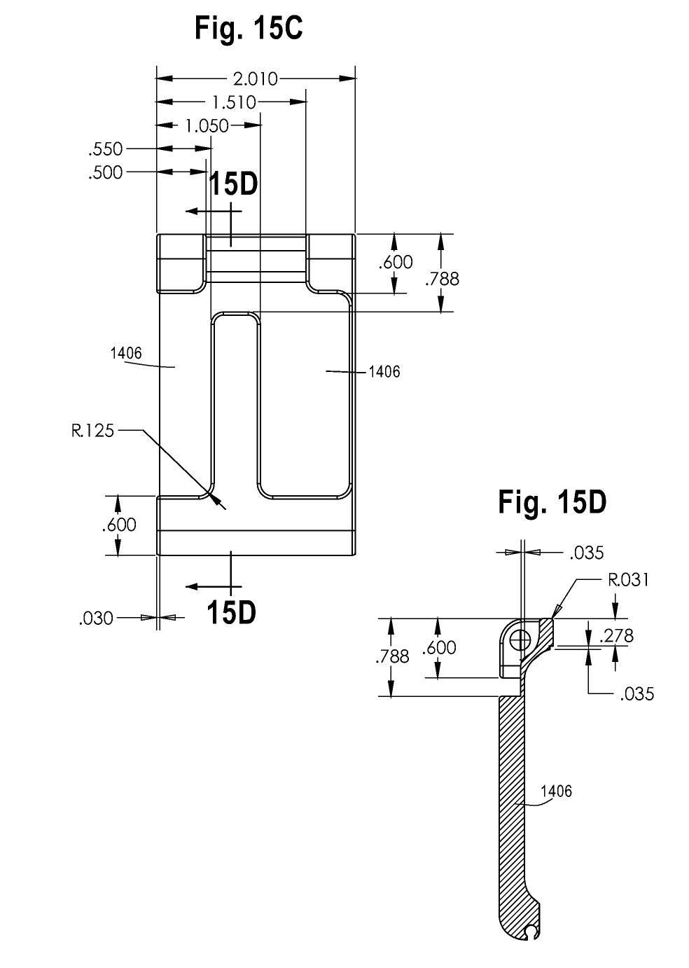

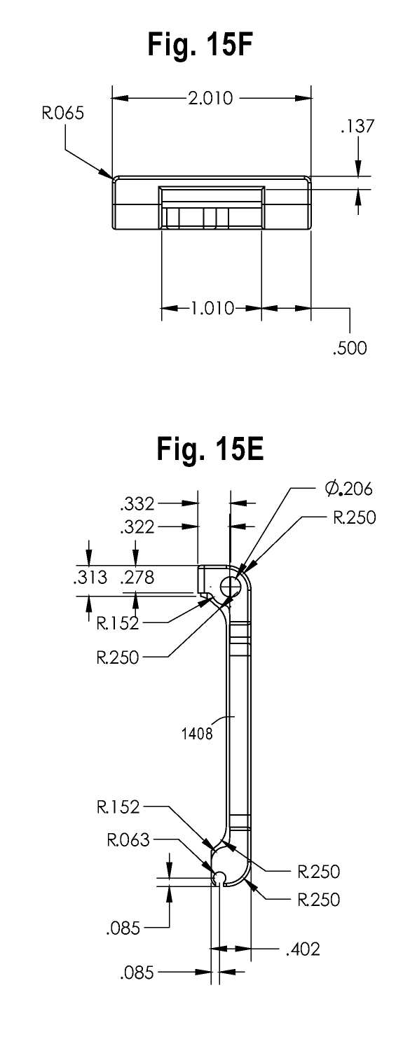

The measurements shown in FIGS. 14 and 15 are approximate and are in inches. FIG. 15 shows the battery door 1400 without the pins 1402, plungers or springs 1404, or battery latch release 226, 1016.

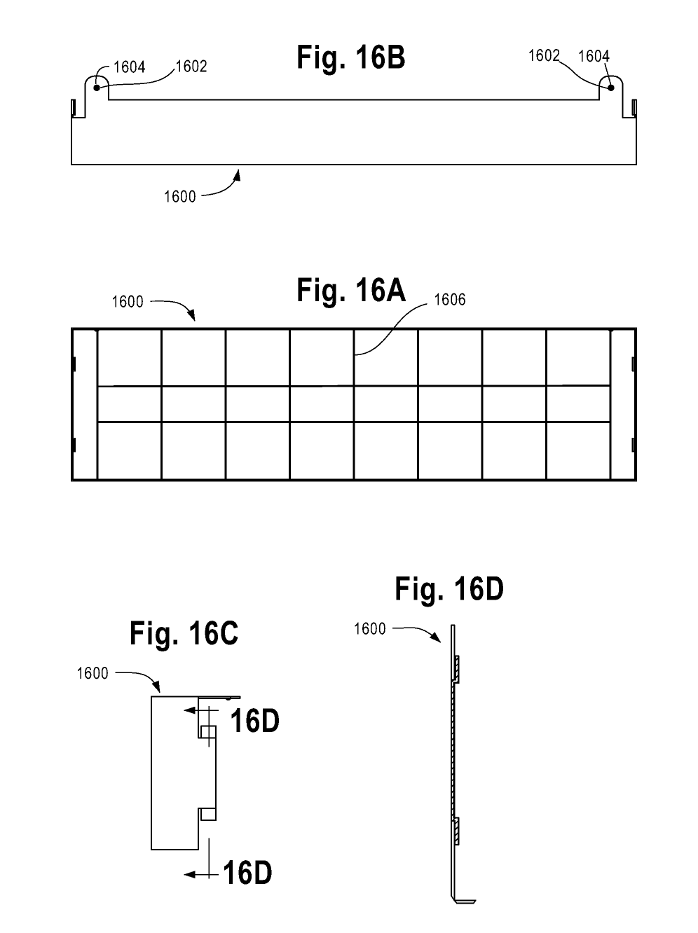

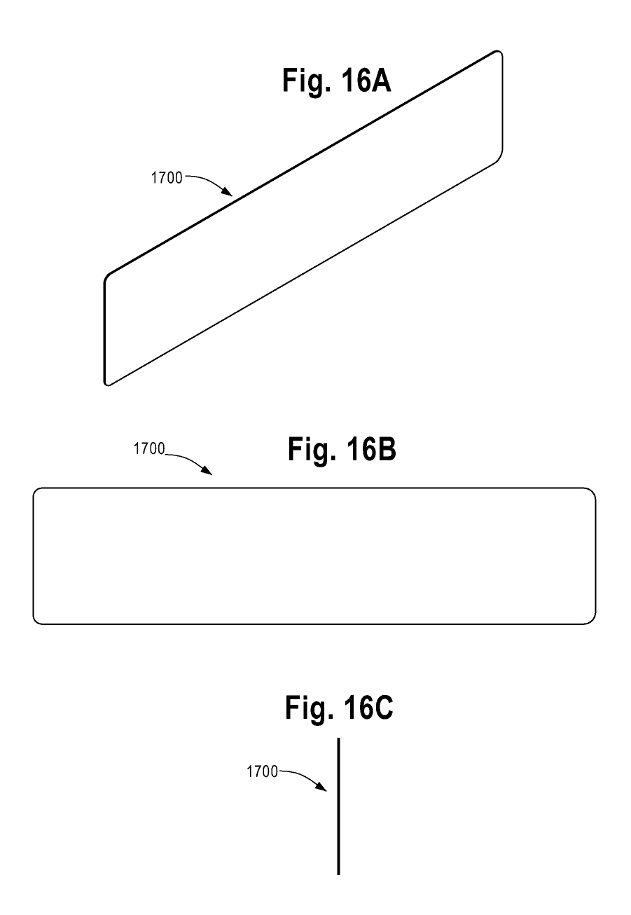

FIG. 16 shows a snoot 1600 that may be used in the lighting device described in this application. In some implementations, the snoot 1600 may be made of metal or plastic. In some implementations having a metal snoot, the snoot 1600 may be made of aluminum. In some implementations, the snoot 1600 may be made of aluminum, steel, plastic, corrugated plastic, or combinations of these materials. In some implementations, the snoot 1600 may be attached to a lighting device through a securing mechanism 1602. As shown, the securing mechanism 1602 is a pin or spring 1604 which permits the snoot 1600 to be connected to the snoot detainer 218 of a lighting device 200.

In some implementations, the securing mechanism 1602 may be a nut, a bolt, a dowel, a lug, a pin, a rivet, a screw, a hook-and-loop fastener, a snap-lock mechanism, a press-fit mechanism, a bracket-type mechanism, a slide-and-lock mechanism, a twist-and-lock or other friction-fit mechanism, a tongue-and-groove mechanism, a buckle mechanism, a joint, or any other suitable mechanism for securing snoot 1600 to the lighting device.

In some implementations, a grid 1606 may be operably connected to the snoot 1600. In some implementations, the grid 1606 may be made of metal or plastic. In implementations having a metal grid, the grid 1606 may be made of aluminum. In some implementations, the grid 1606 may be made of aluminum, steel, plastic, corrugated plastic, or combinations of these materials. When the grid 1606 is present, the grid 1606 may alter the light being generated by the lighting device. The grid 1606 may be connected to the lighting device 200 via the diffuser slot 220.

FIG. 17 shows a lens cover 1700 that may be attached to a lighting device. The lens cover 1700 is made of a material sufficient to permit light to substantially shine through it. The lens cover 1700 may be transparent, substantially transparent, translucent, substantially translucent, opaque, or substantially opaque. In some implementations, the lens cover 1700 is made of borosilicate. In some implementations, the lens cover may be made of glass, Plexiglas, Lucite, Lexan, plastic, polycarbonate, acrylic, or combinations of these materials. In some implementations, the lens cover 1800 is about 11.42 inches wide, about 2.76 inches long, and about 0.028 inches thick.

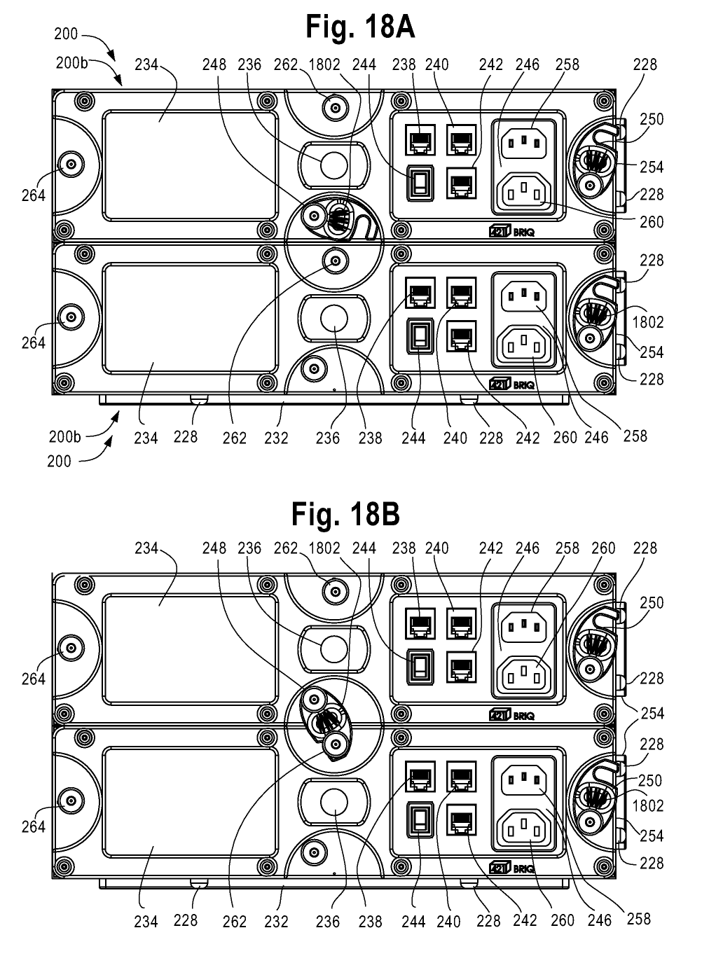

As explained above, an optional latch 248, 250 may be present to secure the lighting device 200 to another lighting device 200 or other object having a corresponding mechanism 262, 264 suitably positioned to make contact with the latch 248, 250. FIG. 18A shows two lighting devices 200, 200 with one lighting device 200a on top of another lighting device 200b. As shown, lighting device 200b does not have latch 248, however, in some implementations, lighting device 200b may have latch 248 present. The latch 248 on lighting device 200b is located at a position substantially corresponding to the location of mechanism 262 on lighting device 200a. As shown in FIG. 18B, when the latch 248 is engaged, the latch 248 makes contact with the mechanism 264 for the connecting the lighting device 200b to the lighting device 200a and accordingly, serves to secure the lighting devices 200a, 200b. Although not shown engaged, in some implementations, latch 250 may work in the same way and have the same construction as latch 248, but latch 250 works with corresponding mechanism 264.

In some implementations, the latch 248 may automatically engage when lighting device 200a is placed on top of lighting device 200b and the latch 248 is substantially aligned with mechanism 264. In some implementations, the latch 248 may be manually engaged when the lighting device 200a is placed on top of lighting device 200b and the latch 248 is substantially aligned with mechanism 264. In some implementations, a user of the lighting device may manually operate the latch 248 by grasping or pressing the latch 248 at location 1802. In some implementations, a button or other mechanism for controlling the latch 248 may be present at location 1802. As a non-limiting example, the latch 248 may be spring-loaded and a button or switch (not shown) at location 1802 may release or engage the latch 248. As another non-limiting example, a groove or ridge may be positioned at location 1802 and a user may grasp the latch 248 at the groove or ridge to engage or disengage the latch 248.

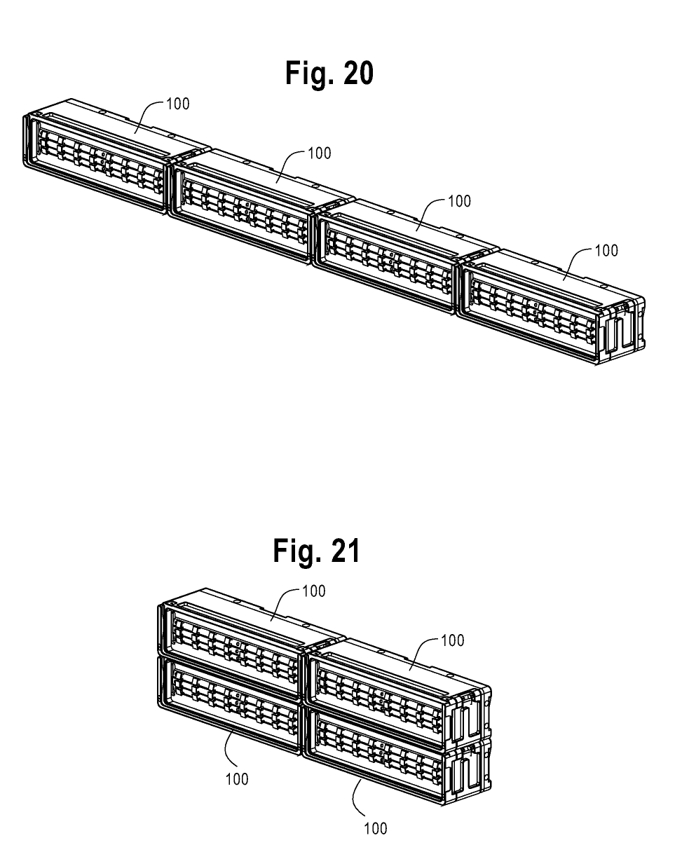

The lighting devices 100, 200 may be connected to each other in many different configurations. Non-limiting examples of two configurations are shown in FIGS. 20 and 21. In some implementations, when the lighting devices are connected to each other, they are operably connected. In some implementations, the lighting devices are electrically connected via the mechanism for A/C power in and distribution 246 located on each lighting device. As a non-limiting example, one end of a cable may be connected to the A/C power in 258 of the mechanism 246 of one lighting device 200 and the other end of the cable may be connected to the A/C power distribution 260 of the mechanism 246 of a second lighting device 200. In some implementations, patch cords may be used to electrically connect the lighting devices. In some implementations where the lighting devices are operably connected to each other, each lighting device may be directly connected to the power source. In some implementations wherein the lighting devices are operably connected, one controller may control all of the operably connected lighting devices instead of one controller being used for each lighting device. In some implementations wherein the lighting devices are operably connected, one controller may control more than one lighting device. In some implementations, the controller may not control all of the lighting devices operably connected to each other. In some implementations, lighting devices may be operably connected via electrical and mechanical connections.

In some implementations wherein a plurality of lighting devices are operably connected to each other, a potentiometer signal may be received at one lighting device and then sent to the lighting devices operably connected to that lighting device, which may permit dimming control of all of the lighting devices at substantially the same time. In some implementations, the potentiometer signal may be transmitted to each lighting device through patch chords or a mechanical connector (not shown). In some implementations, the mechanical connector may be integrated into the lighting devices.

In some implementations, the lighting devices may be capable of being controlled through a remote control via infrared (IR) signals or radio signals. In some implementations, one remote control may control one, more than one, or all of the lighting devices operably connected to each other.

In some implementations, when using the lighting device, electricity enters the lighting device. The electricity is converted to DC current and enters the control circuit. The current then is sent to power the LEDs and light may be emitted from the LEDs.

As shown in the figures and as described above, various measurements have been disclosed. One skilled in the art recognizes that the lighting device may be created using measurements that are different from the measurements disclosed, and the measurements disclosed do not limit the design of the lighting device or the scopes of the features described herein. In addition, the lighting device may be in shapes other than the rectangular shapes shown in the figures. Shapes for the lighting device include, but are not limited to, squares, triangles, circles, ovals, octagons, and spheres, among others.

The housing for the lighting device may be made of materials suitable for the purposes described herein. Non-limiting examples of materials that may be used for the housing are plastic, Plexiglas, glass, metal, rubber, fiberglass, any other material suitable for the purposes described herein, or combinations of these materials. In some implementations, the housing may be made of magnesium, titanium, tungsten, or combinations of these materials. In some implementations the lighting device may be capable of being powered by both A/C current and a battery, and when the lighting device is powered by the A/C current, a mechanism may be present to charge the battery.

A number of implementations have been described. Nevertheless, it will be understood that various modifications may be made without departing from the spirit and scope of the disclosures in this application. As a non-limiting example, additional components may be added to those described above, or components may be removed or rearranged. It is understood by one skilled in the art that the connections and attachments described in this disclosure may be direct or indirect connections and attachments, respectively.

As another non-limiting example, in some implementations, the lighting device may be capable of variably changing the color of the LEDs. As yet another non-limiting example, in some implementations, the lighting device may be configured so that the angle of the LEDs may be adjustable.

As a further non-limiting example, the number of LEDs present in the lighting device may be increased or decreases. In some implementations, the lighting device may have 30 LEDs with each LED being 1″ apart from its adjacent LED. In some implementations, the lighting device may have more than 30 LEDs. In some implementations, the lighting device may have less than 30 LEDs. In some implementations, each LED is spaced less than 1″ apart from its adjacent LED. In some implementations, each LED is spaced apart more than 1″ from its adjacent LED.

As another non-limiting example, in some implementations, the mechanism for connecting the lighting device 200 to at least one other lighting device 200 or other object may be a nut, a bolt, a dowel, a lug, a pin, a rivet, a screw, a hook-and-loop fastener, a snap-lock mechanism, a press-fit mechanism, a bracket-type mechanism, a slide-and-lock mechanism, a twist-and-lock or other friction-fit mechanism, a tongue-and-groove mechanism, a buckle mechanism, a joint, or any other suitable mechanism for securing the lighting device 200 to at least one other lighting device 200 or other object. In some implementations, the mechanism for connecting the lighting device 200 to at least one other lighting device 200 or other object may have a part of the mechanism located on one lighting device 200 and the corresponding or receiving part of the mechanism located on the other lighting device 200 or other object. As a non-limiting example, if the mechanism for connecting the lighting device 200 to at least one other lighting device 200 or other object is a dowel, then the dowel may be located on one lighting device 200 and a corresponding hole for receiving the dowel may be located on a second lighting device 200 or the other object.

As yet another non-limiting example, although shown in the figures as being mounted on horizontal rows, the LEDs may be mounted on vertical columns. In some implementations, LEDs may be mounted on vertical columns and horizontal rows.

As another non-limiting example, in some implementations having more than one horizontal row, the bottom row of LEDs may be angled upwards and the top row angled downwards. As yet a further non-limiting example, an optic or lens may be used with the lighting device to redirect or alter the light emitted from the lighting device. The optic or lens may enable light being emitted from an LED to be emitted at an angle different from the angle corresponding to the angle upon which the LED is mounted. In some implementations, a lighting device may have a plurality of LEDs on the same or substantially the same plane and an optic or lens optically redirects the light so that the light being emitted may be substantially the same as if the LEDs were not all mounted in the same or substantially the same plane. In some implementations, an optic or lens may permit the light being emitted from the lighting device to be emitted in a shape or design, including, but not limited to, a circle, star, square, oval, rectangle, triangle, moon, or any other shape or design. One skilled in the art recognizes that various shapes and designs may be emitted from the optic or lens and they may vary from those specified in the previous sentence. Other implementations are within the scope of the following claims.

What is claimed is:

1. A lighting device comprising:
a housing having a top wall operably connected to a bottom wall wherein the housing has a front and a rear;
a cover operably connected to the rear of the housing;
at least one mechanism located on at least one of the walls of the housing for operably connecting the lighting device to a second lighting device;
a mechanism for holding at least one light-emitting diode, wherein the mechanism for holding the at least one light-emitting diode is operably connected to the front of the housing and a power source;
at least one light-emitting diode installed on the mechanism for holding the at least one light-emitting diode.

2. The lighting device of claim 1, further comprising a lens operably connected to the front of housing, wherein the lens is configured and located to substantially cover the at least one light-emitting diode.

3. The lighting device of claim 1, further comprising a snoot operably connected to the front of the housing.

4. The lighting device of claim 1, wherein the at least one mechanism located on at least one of the walls of the housing for operably connecting the lighting device to a second lighting device comprises a groove.

5. The lighting device of claim 1, wherein the at least one mechanism located on at least one of the walls of the housing for operably connecting the lighting device of a second lighting device comprises a tongue.

6. The lighting device of claim 1, further comprising a battery door assembly operably connected to the housing.

7. The lighting device of claim 6, wherein a battery door assembly is incorporated into at least one of the walls of the housing.

8. The lighting device of claim 1, wherein the housing is made of at least one material selected from the group consisting of plastic, Plexiglas, glass, metal, rubber, and fiberglass.

9. The lighting device of claim 1, wherein the mechanism for holding the at least one light-emitting diode comprises at least one horizontal row.

10. The lighting device of claim 1, wherein the power source is a battery.

11. The lighting device of claim 1, further comprising a control panel operably connected to the at least one light-emitting diode.

12. The lighting device of claim 1, wherein the top and bottom walls are operably connected via at least one side wall.

13. The lighting device of claim 1, further comprising a diffuser slot and a gel slot located on the front of the housing.

14. The lighting device of claim 13, further comprising a retainer mechanism operably connected to the gel slot for retaining gel inserted into the gel slot.

15. The lighting device of claim 14, wherein the retainer mechanism comprises a clip.

16. A lighting device comprising:
a housing having a top wall operably connected to a bottom wall via side walls, wherein the housing has a front and a rear;
a cover operably connected to the rear of the housing;
a first mechanism for operably connecting the lighting device to a second lighting device, wherein the first mechanism is located on at least one of the side walls of the housing;
a second mechanism for operably connecting the lighting device to the second lighting device, wherein the second mechanism is located on at least one of the top wall and bottom wall of the housing;
a mechanism for holding a plurality of light-emitting diodes, wherein the mechanism for holding the plurality of light-emitting diodes is operably connected to the front of the housing and a power source;
a plurality of LEDs installed on the mechanism for holding the plurality of light-emitting diodes.

17. The lighting device of claim 16, further comprising a lens operably connected to the front of the housing, wherein the lens is configured and located to substantially cover the plurality of light-emitting diodes.

18. The lighting device of claim 16, further comprising a snoot operably connected to the front of the housing.

19. The lighting device of claim 16, wherein the first mechanism for operably connecting the lighting device to the second lighting device comprises a groove.

20. The lighting device of claim 16, wherein the first mechanism for operably connecting the lighting device to the second lighting device comprises a tongue.

21. The lighting device of claim 16, wherein the second mechanism for operably connecting the lighting device to the second lighting device comprises a groove.

22. The lighting device of claim 16, further comprising a battery door assembly operably connected to the housing.

23. The lighting device of claim 22, wherein a battery door assembly is incorporated into at least one of the walls of the housing.

24. The lighting device of claim 16, wherein the housing is made of at least one material selected from the group consisting of plastic, Plexiglas, glass, metal, rubber, and fiberglass.

25. The lighting device of claim 16, wherein the mechanism for holding a plurality of LEDs comprises a plurality of horizontal rows.

26. The lighting device of claim 25, wherein the angle of each horizontal row differs from the angle of its adjacent horizontal row.

27. The lighting device of claim 16, wherein the lighting device further comprises a control panel operably connected to the light-emitting diodes.

28. The lighting device of claim 16, further comprising a diffuser slot and a gel slot located on the front of the housing.

29. The lighting device of claim 28, further comprising a retainer mechanism operably connected to the gel slot for retaining gel inserted into the gel slot.

30. The lighting device of claim 29, wherein the retainer mechanism comprises a clip.
